(19) United States
(12) Patent Application Publication
(10) Pub. No.: US 2022/0402260 A1
(43) Pub. Date: Dec. 22, 2022

(54) PRINTING PLATE, PRINTING APPARATUS, AND PRINTING METHOD OF SUBSTRATE

(71) Applicant: SHENZHEN CHINA STAR OPTOELECTRONICS SEMICONDUCTOR DISPLAY TECHNOLOGY CO., LTD., Shenzhen (CN)

(72) Inventors: Bin Zhao, Shenzhen (CN); Juncheng Xiao, Shenzhen (CN); Jia Li, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/419,189

(22) PCT Filed: Dec. 17, 2020
(86) PCT No.: PCT/CN2020/137191

§ 371 Date: Jun. 28, 2021

(30) Foreign Application Priority Data
Mar. 26, 2020 (CN) 202010225266.1

(51) Int. Cl. B41F 15/36

(52) U.S. Cl. CPC B41F 15/36; B41P 2217/50

(57) ABSTRACT

A printing plate, a printing apparatus, and a printing method of a substrate are disclosed. The printing plate includes a flat plate, a raised part is disposed on one side surface of the flat plate, and the raised part is defined with a plurality of printing holes penetrating through the raised part and the flat plate. By disposing the raised part on the side surface of the flat plate, the present disclosure can effectively prevent a large-area contact between the printing plate and a chip-mounting substrate and can reduce a probability of the printing plate scratching solder paste on the chip-mounting substrate. Therefore, short circuits of the chip-mounting substrate can be prevented, and yields of a printing process can be improved.

### FIELD OF INVENTION

The present disclosure relates to the field of printing technologies, and more particularly, to a printing plate, a printing apparatus, and a printing method of a substrate.

### BACKGROUND OF INVENTION

At present, screen printing is called universal printing. A variety of materials to be printed can be printed by the screen printing, such as plastics, textiles, metal, glass, and printed circuit boards. Therefore, it is widely used in industrial fields such as advertising, art, architecture, publishing, printing and dyeing, and electronics. Especially in the electronics industry, screen printing technology has a share of up to 90%, so importance of the screen printing can be seen from this.

Conventional screen-printing machines include racks, alignment components, printing components, and transporting components. The alignment components are disposed on one side of the racks, the printing components are disposed on another side of the racks, substrates to be printed are placed on the alignment components to align in advance, and the transporting components transport the substrates to be printed from the alignment components to the printing components to perform printing.

Technical problem: performing thin film transistor (TFT) processes on glass substrates to drive sub-millimeter light-emitting diode (mini-LED) displays is a new field. However, since the glass substrates are softer and more fragile than printed circuit boards (PCBs), they are prone to deformation in a chip-mounting process of surface mounted technology, thereby causing offsets or breakages of chip-mounting points and reducing yields of printing processes.

### SUMMARY OF INVENTION

An embodiment of the present disclosure provides a printing plate, a printing apparatus, and a printing method of a substrate. By disposing a raised part on one side surface of a flat plate and defining printing holes on the raised part to allow an area of the printing holes on the flat plate to be raised, only the raised part of the printing plate that corresponds to the printing holes is in contact with a chip-mounting substrate in a printing process using the printing plate. The present disclosure can effectively prevent a large-area contact between the printing plate and the chip-mounting substrate and can reduce a probability of the printing plate scratching solder paste on the chip-mounting substrate. Therefore, short circuits of the chip-mounting substrate can be prevented, and yields of the printing process can be improved.

In one aspect, an embodiment of the present disclosure provides the printing plate, which includes the flat plate, the raised part is disposed on the side surface of the flat plate, and the raised part is defined with a plurality of printing holes penetrating through the raised part and the flat plate.

In an embodiment of the present disclosure, a plurality of raised parts are disposed on the side surface of the flat plate, and the raised parts are arranged at intervals.

In an embodiment of the present disclosure, the raised parts are arranged in an array.

In an embodiment of the present disclosure, the raised part is defined with the printing holes arranged in an array.

In an embodiment of the present disclosure, a depth of the printing holes ranges from 0.05 mm to 2 mm.

In an embodiment of the present disclosure, a height of the raised parts ranges from 0.01 mm to 1 mm.

In an embodiment of the present disclosure, the printing holes are rectangular or circular.

In an embodiment of the present disclosure, the printing plate is a metal material.

In another aspect, an embodiment of the present disclosure provides the printing apparatus, which includes a printing table and a printing plate adapted to the printing table; wherein, the printing plate includes a flat plate, a raised part is disposed on one side surface of the flat plate, and the raised part is defined with a plurality of printing holes penetrating through the raised part and the flat plate.

In an embodiment of the present disclosure, a plurality of raised parts are disposed on the side surface of the flat plate, and the raised parts are arranged at intervals.

In an embodiment of the present disclosure, the raised parts are arranged in an array.

In an embodiment of the present disclosure, the raised part is defined with the printing holes arranged in an array.

In an embodiment of the present disclosure, a depth of the printing holes ranges from 0.05 mm to 2 mm.

In an embodiment of the present disclosure, a height of the raised parts ranges from 0.01 mm to 1 mm.

In an embodiment of the present disclosure, the printing holes are rectangular or circular.

In an embodiment of the present disclosure, the printing plate is a metal material.

In yet another aspect, an embodiment of the present disclosure provides the printing method of the substrate, which includes following steps:

providing the printing apparatus mentioned above;

providing the chip-mounting substrate; and

printing the chip-mounting substrate using the printing apparatus.

Beneficial effect: the printing plate provided in the embodiment of the present disclosure includes the flat plate, the raised part is disposed on the side surface of the flat plate, and the raised part is defined with the plurality of printing holes penetrating through the raised part and the flat plate. By disposing the raised part on the side surface of the flat plate and defining the printing holes on the raised part to allow the area of the printing holes on the flat plate to be raised, only the raised part of the printing plate that corresponds to the printing holes is in contact with the chip-mounting substrate in the printing process using the printing plate. The embodiments of the present disclosure can effectively prevent the large-area contact between the printing plate and the chip-mounting substrate and can reduce the probability of the printing plate scratching the solder paste on the chip-mounting substrate. Therefore, the short circuits of the chip-mounting substrate can be prevented, and the yields of the printing process can be improved.

### DESCRIPTION OF DRAWINGS

The following detailed description of specific embodiments of the present disclosure will make the technical solutions and other beneficial effects of the present disclosure obvious with reference to the accompanying drawings.

FIG. 1 is a schematic front-view structural diagram of a printing plate according to an embodiment of the present disclosure.

FIG. 2 is a schematic top-view structural diagram of the printing plate according to an embodiment of the present disclosure.

FIG. 3 is a flowchart of a printing method of a substrate according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or implicitly indicating the number of technical features indicated. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrated connection; it can mean a mechanical connection, an electrical connection, or can communicate with each other; it can mean a direct connection, an indirect connection by an intermediate, or an inner communication or an interreaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The following description provides many different embodiments or examples for implementing different structures of the present disclosure. In order to simplify the present disclosure, the components and settings of a specific example are described below. Of course, they are merely examples and are not intended to limit the present disclosure. In addition, the present disclosure may repeat reference numerals and/or reference letters in different examples, which are for the purpose of simplicity and clarity, and do not indicate the relationship between the various embodiments and/or arrangements discussed. In addition, the present disclosure provides examples of various specific processes and materials, but one of ordinary skill in the art will recognize the use of other processes and/or the use of other materials.

An embodiment of the present disclosure provides a printing plate, a printing apparatus, and a printing method of a substrate. They will be described in detail in the following.

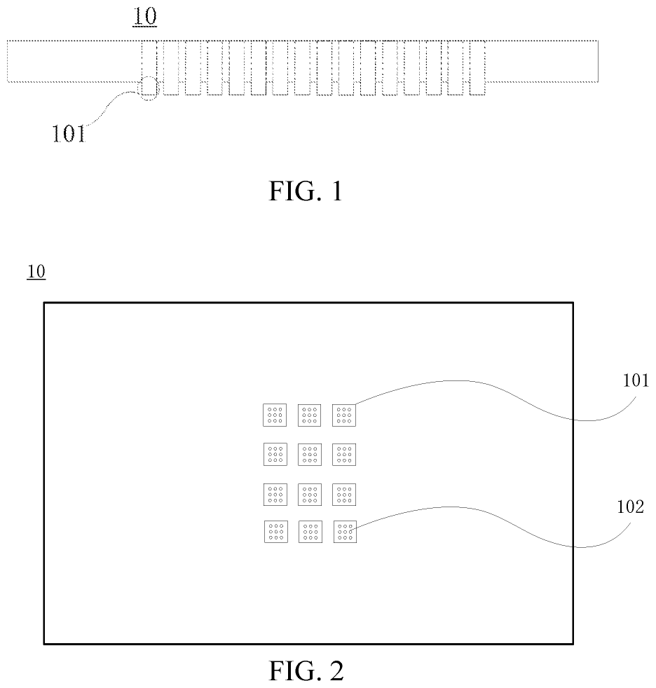

Referring to FIGS. 1 and 2, FIG. 1 is a schematic front-view structural diagram of the printing plate according to an embodiment of the present disclosure, and FIG. 2 is a schematic top-view structural diagram of the printing plate according to an embodiment of the present disclosure. Wherein, the printing plate includes a flat plate 10, a raised part 101 is disposed on one side surface of the flat plate 10, and the raised part 101 is defined with a plurality of printing holes 102 penetrating through the raised part 101 and the flat plate 10.

In this embodiment, the printing plate is used in surface mounted technology (SMT). Wherein, SMT is a circuit assembling technology, which mounts surface mounted components (SMCs) or surface mounted devices (SMDs) that have no pins or have short leads onto surfaces of printed circuit boards (PCBs) or other substrates and welds them together by over reflow soldering or dip soldering.

In summary, by disposing the raised part 101 on the side surface of the flat plate 10 and defining the printing holes 102 on the raised part 101 to allow an area of the printing holes 102 on the flat plate 10 to be raised, only the raised part 101 of the printing plate that corresponds to the printing holes 102 is in contact with a chip-mounting substrate in a printing process using the printing plate. The embodiments of the present disclosure can effectively prevent a large-area contact between the printing plate and the chip-mounting substrate and can reduce a probability of the printing plate scratching solder paste on the chip-mounting substrate. Therefore, short circuits of the chip-mounting substrate can be prevented, and yields of the printing process can be improved.

In some embodiments of the present disclosure, a plurality of raised parts 101 are disposed on the side surface of the flat plate 10, and the raised parts 101 are arranged at intervals. Specifically, the raised parts 101 correspond to the printing holes 102, the printing holes 102 correspond to practical printing structures, and spacings among the raised parts 101 are not limited herein and may be determined by practical situations.

The printing holes on the printing plate correspond to screen printing markings that need to be printed on the printed circuit boards by one to one.

In some embodiments, the raised parts 101 are arranged in an array, and each of the raised parts 101 is defined with the printing holes 102 arranged in an array. Wherein, a depth of the printing holes 102 ranges from 0.05 mm to 2 mm, and for example, the depth of the printing holes 102 may be 1 mm. Further, the printing holes 102 may be rectangular or circular and specifically, may be determined according to practical situations.

In some embodiments, a height of the raised parts 101 ranges from 0.01 mm to 1 mm. In this embodiment, setting the height of the raised parts 101 to range from 0.01 mm to 1 mm can realize that only the raised parts 101 of the printing plate that correspond to the printing holes 102 are in contact with the chip-mounting substrate in the printing process using the printing plate. Therefore, it can effectively prevent the large-area contact between the printing plate and the chip-mounting substrate and can reduce the probability of the printing plate scratching the solder paste on the chip-mounting substrate, thereby preventing the short circuits of the chip-mounting substrate and improving the yields of the printing process. Meanwhile, setting the height of the raised parts 101 to range from 0.01 mm to 1 mm can allow the printing plate to have certain stability in the printing process.

In some embodiments, the printing plate is a metal material. For example, the printing plate may be a steel material or other metal materials and may be determined according to practical situations.

In order to better implement the printing plate of the present disclosure, an embodiment of the present disclosure further provides the printing apparatus, which includes a printing table and the printing plate adapted to the printing table.

In this embodiment, the printing holes and the raised parts corresponding to the printing plate may be plural. Specifically, numbers of the printing holes and the raised parts and relative positions thereof may be designed according to practical situations, and the printing plate can be adapted to various printing apparatuses.

In summary, by disposing the raised parts 101 on the side surface of the flat plate 10 and defining the printing holes 102 on the raised parts 101 to allow the area of the printing holes 102 on the flat plate 10 to be raised, only the raised parts 101 of the printing plate that correspond to the printing holes 102 are in contact with the chip-mounting substrate in the printing process using the printing plate. The embodiments of the present disclosure can effectively prevent the large-area contact between the printing plate and the chip-mounting substrate and can reduce the probability of the printing plate scratching the solder paste on the chip-mounting substrate. Therefore, the short circuits of the chip-mounting substrate can be prevented, and the yields of the printing process can be improved.

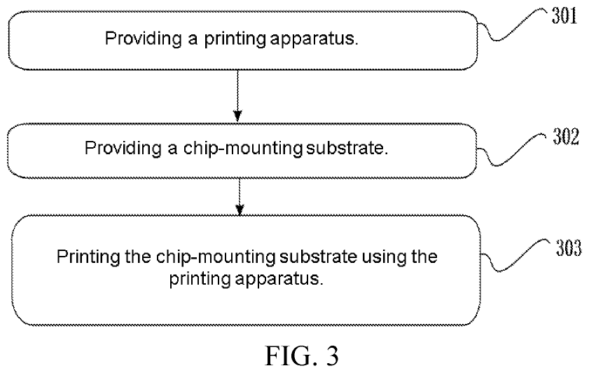

In order to better implement the printing plate of the present disclosure, an embodiment of the present disclosure further provides the printing method of the substrate. As shown in FIG. 3, FIG. 3 is a flowchart of the printing method of the substrate according to an embodiment of the present disclosure. The method includes following steps.

301: Providing the printing apparatus mentioned in the above embodiments.

302: Providing the chip-mounting substrate.

303: Printing the chip-mounting substrate using the printing apparatus.

Specifically, this embodiment generally uses screen printing, which generally consists of the printing plate, a squeegee, inks, the printing table, and a substrate to be printed. The screen printing uses a basic principle of meshes having graphic and text parts on the printing plate allowing the inks to penetrate and meshes having no graphic and text parts allowing no inks to penetrate for printing.

When printing, the inks are poured to one end of the printing plate, and the squeegee is used to apply certain pressure on the inks on the printing plate and move to another end of the printing plate at a same time. The inks are squeezed to the substrate to be printed from the meshes having the graphic and text parts by the squeegee when moving.

Imprints are fixed within a certain range due to stickiness of the inks. In the printing process, the squeegee is always in a line contact with the printing plate and the substrate to be printed, and a contact line moves with movements of the squeegee. Since a certain gap is maintained between the printing plate and the substrate to be printed, the printing plate during printing generates a reaction force to the squeegee by its own tension, and this reaction force is called a resilience force. Due to an effect of the resilience force, the printing plate and the substrate to be printed only have a mobile line contact, and other parts of the printing plate are not in contact with the substrate to be printed. Therefore, the inks may be detached from stencils, thereby ensuring accuracy of printing sizes and preventing the substrate to be printed from being rubbed and becoming dirty. When the squeegee scrapes across entire substrate and lifts up, the printing plate lifts up at a same time, and the inks are gently scraped back to an initial position. So far, the above is the printing process.

In some embodiments, the step of printing the chip-mounting substrate using the printing apparatus includes following steps: laying the stencils on the chip-mounting substrate and using the squeegee to print the chip-mounting substrate laid with the stencils.

In some embodiments, the step of using the squeegee to print the chip-mounting substrate laid with the stencils includes following steps: laying the stencils on the chip-mounting substrate, adjusting a relative position between the squeegee and the stencils to align the squeegee with the stencils, and printing the chip-mounting substrate.

In summary, by disposing the raised parts 101 on the side surface of the flat plate 10 and defining the printing holes 102 on the raised parts 101 to allow the area of the printing holes 102 on the flat plate 10 to be raised, only the raised parts 101 of the printing plate that correspond to the printing holes 102 are in contact with the chip-mounting substrate in the printing process using the printing plate. The embodiments of the present disclosure can effectively prevent the large-area contact between the printing plate and the chip-mounting substrate and can reduce the probability of the printing plate scratching the solder paste on the chip-mounting substrate. Therefore, the short circuits of the chip-mounting substrate can be prevented, and the yields of the printing process can be improved.

In the above embodiments, the description of each embodiment has its own emphasis. For the parts that are not described in detail in an embodiment, can refer to the detailed description of other embodiments above.

The printing plate, the printing apparatus, and the printing method of the substrate provided in the embodiments of the present disclosure are described in detail above. Specific examples are used herein to explain the principles and implementation of the present disclosure. The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

What is claimed is:

1. A printing plate, comprising a flat plate, wherein a raised part is disposed on one side surface of the flat plate, and the raised part is defined with a plurality of printing holes penetrating through the raised part and the flat plate.

2. The printing plate according to claim 1, wherein a plurality of raised parts are disposed on the side surface of the flat plate, and the raised parts are arranged at intervals.

3. The printing plate according to claim 2, wherein the raised parts are arranged in an array.

4. The printing plate according to claim 1, wherein the raised part is defined with the printing holes arranged in an array.

5. The printing plate according to claim 1, wherein a depth of the printing holes ranges from 0.05 mm to 2 mm.

6. The printing plate according to claim 4, wherein a depth of the printing holes ranges from 0.05 mm to 2 mm.

7. The printing plate according to claim 1, wherein a height of the raised part ranges from 0.01 mm to 1 mm.

8. The printing plate according to claim 2, wherein a height of the raised parts ranges from 0.01 mm to 1 mm.

9. The printing plate according to claim 3, wherein a height of the raised parts ranges from 0.01 mm to 1 mm.

10. The printing plate according to claim 1, wherein the printing holes are rectangular or circular.

11. The printing plate according to claim 1, being a metal material.

12. A printing apparatus, comprising a printing table and a printing plate adapted to the printing table;
wherein the printing plate comprises a flat plate, a raised part is disposed on one side surface of the flat plate, and the raised part is defined with a plurality of printing holes penetrating through the raised part and the flat plate.

13. The printing apparatus according to claim 12, wherein a plurality of raised parts are disposed on the side surface of the flat plate, and the raised parts are arranged at intervals.

14. The printing apparatus according to claim 13, wherein the raised parts are arranged in an array.

15. The printing apparatus according to claim 12, wherein the raised part is defined with the printing holes arranged in an array.

16. The printing apparatus according to claim 12, wherein a depth of the printing holes ranges from 0.05 mm to 2 mm.

17. The printing apparatus according to claim 12, wherein a height of the raised part ranges from 0.01 mm to 1 mm.

18. The printing apparatus according to claim 12, wherein the printing holes are rectangular or circular.

19. The printing apparatus according to claim 12, being a metal material.

20. A printing method of a substrate, comprising following steps:
providing the printing apparatus according to claim 12;
providing a chip-mounting substrate; and
printing the chip-mounting substrate using the printing apparatus.
